(19) United States
(12) Patent Application Publication
(10) Pub. No.: US 2010/0022416 A1
(43) Pub. Date: Jan. 28, 2010

(54) ASSAY PLATES, METHODS AND SYSTEMS HAVING ONE OR MORE ETCHED FEATURES

(75) Inventors: Jeb H. Flemming, Albuquerque, NM (US); Colin T. Buckley, Albuquerque, NM (US); Blake Ridgeway, Albuquerque, NM (US)

Correspondence Address: CHALKER FLORES, LLP, 2711 LBJ FRWY, Suite 1036, DALLAS, TX, 75234, US

(73) Assignee: Life BioScience, Inc., Albuquerque, NM (US)

(21) Appl. No.: 12/509,186

(22) Filed: Jul. 24, 2009

Related U.S. Application Data
(60) Provisional application No. 61/083,843, filed on Jul. 25, 2008.

(51) Int. Cl. C40B 60/12; C23F 1/00; G01R 27/28

(52) U.S. Cl. 506/39; 216/11; 324/654; 977/773; 977/888; 977/904

(57) ABSTRACT

The present invention includes composition, methods of making and methods of using a multi-nano-well plate having a first layer at least partially disposed on the substrate and one or more nano-wells that extends through the first layer that extends toward the substrate, wherein the one or more nano-wells having an opening in the first layer connected to bottom layer by one or more walls.

### CROSS-REFERENCE TO RELATED APPLICATIONS

This application claims priority to U.S. Provisional Application Ser. No. 61/083,843, filed Jul. 25, 2008, the contents of which is incorporated by reference herein in its entirety.

### TECHNICAL FIELD OF THE INVENTION

The present invention relates in general to the field of plates, plate components, kits, apparatuses and methods for conducting chemical, biochemical and/or biological assays.

### BACKGROUND OF THE INVENTION

Without limiting the scope of the invention, its background is described in connection with methods, compositions and devices used in chemical, biochemical and/or biological assays and more specifically nano-well titer plates.

There have been numerous methods and systems developed for conducting chemical, biochemical and/or biological assays for use in a variety of applications including medical diagnostics, food and beverage testing, environmental monitoring, manufacturing quality control, drug discovery and basic scientific research. In addition, the specific characteristics are dependent on the specific application. For example, there are commercially available instruments that utilize electrochemiluminescence (ECL) for analytical measurements. Species that can be induced to emit ECL (ECL-active species) have been used as ECL labels.

Commercially available ECL instruments have demonstrated exceptional performance with excellent sensitivity, dynamic range, precision, and tolerance of complex sample matrices; however, these instrumentation uses flow cell-based designs with permanent reusable flow cells that often limit the assay throughput. This low throughput is a problem in the context of screening of chemical libraries for potential therapeutic drugs, assay.

For example, includes U.S. Pat. No. 6,977,722, entitled, “Assay Plates, Reader Systems And Methods For Luminescence Test Measurements,” discloses luminescence test measurements are conducted using an assay module having integrated electrodes with a reader apparatus adapted to receive assay modules, induce luminescence, preferably electrode induced luminescence, in the wells or assay regions of the assay modules and measure the induced luminescence.

A variety of techniques have been developed for increasing assay throughput. The use of multi-well assay plates allows for the parallel processing and analysis of multiple samples distributed in multiple wells of a plate. These techniques use samples and reagents that are stored, processed and/or analyzed in multi-well assay plates (also known as micro-plates or micro-titer plates). Multi-well assay plates can take a variety of forms, sizes and shapes. For convenience, some standards have appeared for some instrumentation used to process samples for high throughput assays. Multi-well assay plates typically are made in standard sizes and shapes and having standard arrangements of wells.

Commercially available assay plates are limited in the number of samples that may be assayed at one time due to the well size and surface area needed for analysis. Generally, the assay plates have a standard number of wells, e.g., 96, 384, 1056 and 1536. These plates well sizes are limited by electrodes and/or the efficient collection of light emitted from the surface of such electrodes. The dimensional problems grow even more difficult when plates having even higher well concentrations are considered. Other considerations include cross contamination and reusability issues including washing and so forth.

### SUMMARY OF THE INVENTION

The present inventors recognized that current microtiter plates, such as 96 or 1056 well titer plates, are difficult and problematic to wash while crowding the wells onto a microtiter plate results in cross contamination of samples between adjacent wells. In addition, nonadherent or motile cells may migrate between the wells again contaminating wells.

The present invention addresses the problems associated with current titer plates and providing micro-posts or micro-Needles that can be used to couple cells and a variety of biomolecules such as, DNA, RNA, PNA, lipids, carbohydrates, ligands, receptors, pharmaceuticals, antigens, allergens, cells, antibodies, peptides, proteins, polymers, monomers, histones, other biomolecules, synthetic molecules and/or complexes for high throughput screening (HTS) assays for drug discovery and much more.

One embodiment of the present invention provides a high throughput screening device that can be used in drug discovery, protein analysis, ELISA, Antibody based microarray, qPCR, RT-PCR, FRET, cell based assays, High Throughput Screening and High Content Screening, electrochemistry and other medical and biological research.

The present invention provides a device that includes a high density number of wells located within a set area, such as a standard microtiter plate or microscope slide format, created from APEX glass, ORACLE glasses, plastics, other glasses, or other manufacturable materials.

The present invention provides a multi-well plate having a first layer at least partially disposed on the substrate and one or more nano-wells that extends through the first layer that extends toward the substrate, wherein the one or more nano-wells comprising an opening in the first layer connected to bottom layer by one or more walls.

The present invention also includes a nano-array plate having a first layer at least partially disposed on a substrate with one or more nano-wells that extends through the first layer that extends toward the substrate. The one or more nano-wells comprising an opening in the first layer connected to bottom layer by one or more walls and one or more micro-posts or micro-Needles extending upwardly from the bottom of the nano-well or extending downwardly from a separate substrate into at least one or more of the nano-wells, or a combination thereof.

The present invention includes a method of forming a nano-array titer plate by providing a first layer in contact with a substrate and forming one or more nano-wells in the first layer to form a nano-array titer plate, wherein each of the one or more nano-wells comprise an opening connected to a bottom layer by one or more side walls. The nano-array titer plate comprising more than 1,000 nano-wells. The substrate is formed by positioning a working electrode at a first depth in the substrate, covering the working electrode with a passive layer, uncovering a portion of the passive layer that corresponds to the one or more nano-wells, positioning a second electrode in proximity to the working electrode and bonding the substrate to the first layer. One or more micro-posts or micro-Needles may be made to extending upwardly from the bottom of at least one of the one or more nano-wells, or extending downwardly from a separate substrate into at least one or more of the nano-wells, or a combination thereof, with each of the one or more nano-wells are between about 150 microns and 1000 microns in diameter and each of the one or more micro-posts or micro-Needles are between about 25 and 100 microns.

The present invention also includes a method of measuring electrode induced property in a nano-well assay array having more than 100,000 nano-wells by providing a nano-well assay array, providing electrical energy to the first electrode, the second electrode or both the first and second electrodes and measuring electrode induced property generated in each of the more than 100,000 nano-wells. The nano-well assay array includes a first layer at least partially disposed on a substrate, more than 100,000 nano-wells that extend through the first layer toward the substrate, wherein each of the more than 100,000 nano-wells comprising an opening in the first layer connected to bottom layer by one or more walls and a first electrode and a second electrode within the more than 100,000 nano-wells.

### BRIEF DESCRIPTION OF THE DRAWINGS

For a more complete understanding of the features and advantages of the present invention, reference is now made to the detailed description of the invention along with the accompanying figures and in which:

FIGS. 1A-1E are schematics representing some of the various approaches to microfabricating nano-titer plates of the present invention;

FIG. 1F is an image of a microscope slide having numerous nano-wells of the present invention;

FIG. 1G is an image of two titer plates having numerous nano-wells of the present invention;

FIG. 2 is a top view of a schematic of an orthogonal isolated electrodes for electro-analysis and electro-technique activities using the nano-titer plates of the present invention;

FIG. 3 is an image of a single well of a nano-titer plate illustrating the use of a conductive micro-posts or micro-Needles for electro-analytical analysis and/or cellular lysing;

FIG. 4 is an image of a single well of a titer plate illustrating the use of an optically transparent micro-posts or micro-Needles for optical interrogation of fluid sample;

FIG. 5 is an image of a single well of a titer plate illustrating the use of a hollow micro-post or micro-Needles for fluid transfer into or out of a nano-well;

FIG. 6 is an image of a single straight wall nano-well of a titer plate with a micro-posts or micro-Needles used to hermetically the seal nano-well;

FIG. 7A is an image of a portion nano-titer plate;

FIG. 7B is an image of a nano-titer plate capture of live S. cerevisiae fluorescing with green fluorescent protein;

FIGS. 8A and 8B are images of a nano-titer plate including a micro-post within the nano-well;

FIG. 9A is an image of unetched biological binding areas are used and FIG. 9B is an image of an etched surface that removes glass to glass-ceramic to expose more surface area to provide a topography roughly the same in every binding area no matter how rough or smooth the binding area; and

FIG. 10 is an image of a light based assay having posts extending from the surface of the substrate.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

As used herein, the term “substrate” denotes a variety of different substances including glass, polymeric materials, agent binding surfaces, plastics, other glasses, or other manufacturable materials ceramic, metal, resin, gel, glass, silicon, glass-ceramics and composites thereof.

As used herein, the term “nano-well” is used to encompass and interchangeably with the term etched feature.

As used herein, the term “first layer” denotes a layer but may encompass multiple layers or partial layers.

As used herein, the term “Agent binding surfaces” denotes APEX binding glass and/or ORACLE binding glass or other manufacturable materials, such as organic thin films, that binds one or more agents.

As used herein, the term “well” or “etched feature” denotes a cavity, which may have a variety of different sizes shapes and depths. For example, the wells can be fabricated from 0.1 microns to millimeters in critical dimension (e.g. diameter, length, width, and depth), as well as a variety of shapes such as circles, triangles, cones, polygons, rectangles, ovals or squares and various depths.

As used herein the terms “multi-well assay module”, “multi-well plate” and “titer plate” are used interchangeably to denote a multi-welled plate.

As used herein the term “micro-post(s)” is used to denote a micro or nano scale post, peg, pin, needle, cylinder, rod, tube, stud, or other member. In addition, the end may have a tip with variety of shapes and/or features, e.g., rounded, blunt, sharp, angled, tapered, flat, sloped, undulating, jagged, other suitable or combination thereof.

As used herein, the term APEX binding glass is used to denote a composition as disclosed in U.S. application Ser. No. 12/058,608, and U.S. provisional Patent Application Ser. No. 60/968,325 both of which are incorporated herein by reference. Generally, the composition includes, by weight, of 71.66% silicon oxide (SiO₂), 0.75% boron oxide (B₂O₃), 0.4% antimony trioxide (Sb₂O₃), 11% lithium oxide (Li₂O), 6% aluminum oxide (Al₂O₃), 2% sodium oxide (Na₂O), 0.15% silver oxide (Ag₂O), and 0.04% cerium oxide (CeO₂) of by weight, and exposing one portion of the photosensitive glass substrate with ultraviolet light (305 nm to 315 nm) using an activation exposure of 9 J/cm², while leaving a second portion of said glass wafer unexposed. The binding substrate was heated to a temperature of 500° C. for one hour and then to a temperature of 600° C. for one hour and then cooled to transform at least part of the exposed glass to a crystalline material. The substrate was then etched in an HF-containing etchant solution.

The present invention provides a mechanism and substrate to allow biological molecules to attach to defined areas of ceramic, bounded by glass, formed by spaced-apart metal nanoparticles with a subsequent bake and etch step. Target molecules in solution, can attach to the bound biological molecules and, with a suitable fluorescent marker target molecules can be detected. For example, a number of possible capture-detection configurations are possible such as antigen-antibody, antibody-antigen, Sandwich ELISA, aptamers, enzyme-substrate, receptor-ligand, protein-drug, protein-liposome, and antibody-carbohydrate. While fluorescence detection methods are preferred method of detection due to its simple, safe, extremely sensitive nature and high resolution, other methods of detection are also possible such a rolling circle amplification, radioisotope labeling, surface-enhanced laser desorption/ionization (SELDI) mass spectrometry, atomic force microscopy, as well as surface plasmon resonance, planar waveguide, and electrochemical detection are all possible with these surfaces.

The present invention provides a method of forming one or more biological-binding areas on a substrate for biological-testing. The method includes activating at least a portion of a glass-ceramic substrate comprising glass and one or more metal containing compounds. The one or more metal containing compounds have a range of diameters that are less than about 300 nanometers in diameter and are spaced an average distance of at least one-half the midpoint of the diameter range apart. The one or more metal include compounds selected from metal oxides, metal nanoparticles, metal alloys, and atomic metals. The glass-ceramic substrate is heated to a temperature near the glass transformation temperature to form one or more metal nanoparticles in one or more ceramic biological-binding areas. The glass-ceramic substrate is etched to expose one or more metal. One or more biological molecules are contacted with one or more ceramic biological-binding areas to provide one or more biological testing areas with an increased binding area as compared to unactivated areas

The patterning one or more discrete binding areas on the glass-ceramic substrate to form one or more metal nanoparticles within the one or more discrete binding areas may be accomplished in various ways known to the skilled artisan. For example, screen printing, photo lithography or a combination thereof may be used to form a pattern mask on at least a portion of the glass-ceramic substrate to protect at least a portion of the glass-ceramic substrate from activation to form one or more discrete binding areas. Similarly, screen printing photo lithography or a combination thereof may be used to form an etching pattern mask on at least a portion of the glass-ceramic substrate to protect at least a portion of the glass-ceramic substrate from etching to form one or more discrete binding areas.

The step of activating includes metal-precipitating one or more metal nanoparticles from metal oxides and the step of heating comprises metal-coalescing baking the glass-ceramic substrate. Although many different mechanisms may be used in the activation step, one common mechanism includes exposing at least a portion of a glass-ceramic substrate to an activating energy source. The one or more metal oxides are exposed to high-energy particles to reduce the one or more metal oxides to one or more metal nanoparticles.

The one or more metal nanoparticles are assayed by techniques using surface plasmon excitation, e.g., surface enhanced fluorescence (SEF), metal enhanced fluorescence (MEF), surface enhanced Raman scattering (SERS), surface plasmon resonance (SPR) or surface enhanced resonance Raman scattering (SERRS).

The present invention provides a patterned biological-binding substrate for biological-testing having a glass-ceramic substrate comprising one or more glass areas and one or more ceramic biological-binding areas comprising exposed metal nanoparticles, wherein at least half of the one or more metal nanoparticles are 1-500 nanometers in diameter and spaced from other metal particles by an average distance of at least 2 nanometers, wherein the one or more ceramic biological-binding areas provide greater binding than the one or more glass areas.

The present invention shows a dramatically enhanced binding and attachment of biological molecules using defined areas of ceramic, bounded by glass, formed by the creation of spaced-apart metal nanoparticles with a subsequent bake and etch step, rather than surface areas of either metal or glass. It is well understood that the distortion of a biological molecule bound to surfaces can reduce the ability to bind target molecules. The present invention provides a surface which binds biological molecules and causes minimal, or zero, conformational distortion, to enable the bound biological molecule to more efficiently bind target molecules. The binding of the target molecule to the biological molecule may be detected using a variety of techniques, including fluorescent detection.

Preferably, the substrates are transparent or translucent to provide for convenient optical sensing, e.g. using fluorescent markers. In many preferred embodiments, photosensitive glass structures are used herein for the biological-binding surfaces (e.g. as a selected portion of a photosensitive glass substrate, using a thin photosensitive glass coating on a non-photosensitive substrate; or photosensitive glass micro-spheres deposited onto a non-photosensitive substrate). Photosensitive glass can provide an inexpensive and practical method of creating defined areas of ceramic, bounded by glass, formed by the creation of spaced-apart metal nanoparticles with a subsequent bake and etch step.

These metal nanoparticles can be comprised of metals with the ability to bind non-bound electron pairs present on various molecules in solution. These metals may consist of high-protein-affinity elements like silver, gold, platinum, rhodium, palladium, cerium, nickel, cobalt, copper, or their alloys or combinations of these metals or alloys. The substrate housing the metal nanoparticles may consist of glass, plastics, organic films (e.g. nitrocellulous, polystyrene, sol-gels, etc); and/or ceramics. In some embodiments, low-or-no-protein-affinity metals such as aluminum or zinc may be used for the substrate. Thus, the present invention uses metal nanoparticles in a lower-or-no-metal nanoparticle substrate. The present invention obtained dramatically improved binding results with such an arrangement. The present inventors believe that such spaced-apart metal nanoparticles greatly reduce biological molecule conformational distortion and thus greatly improve target molecule binding to biological molecules.

The present invention provides an inexpensive and rapid method for fabricating a pattern of biological binding areas for biological-testing, using defined areas of ceramic, bounded by glass, formed by the creation of spaced-apart metal nanoparticles with a subsequent bake and etch step, on a substrate. Biological molecules can be attached to ceramic through a variety of mechanisms, and the areas can provide a chemistry for increased biological binding as compared to unpatterned areas. The patterning may be fabricated using a variety of processes, such as exposing areas of a photosensitive glass substrate to create areas of metal nanoparticles via energy transfer, containing micro-particles or nanoparticles (e.g. of at least one of silver, gold, platinum, rhodium, palladium, cerium, nickel, cobalt, and copper, or their alloys or combinations of these metals or alloys) on/in a substrate.

Patterning of the areas may be accomplished by at least one process step selected from the group consisting of, exposing the material to an activating energy source (e.g. UV light to reduce a metal-oxide to metal), baking the material having a glass transition temperature at a temperature above said glass transition temperature (e.g. to allow metal atoms to coalesce into metal micro-or-nanoparticles), etching of areas to expose metal nanoparticles from within a substrate (e.g. where the metal micro-or-nanoparticles are etched slowly, if at all, compared to other material in the substrate, e.g. silver particles in a glass substrate etched with HF to increase the surface area and the exposure or near-exposure of metal particles); and depositing patterned areas of biological-binding-glass (e.g. thermal evaporation or micro-spheres containing metal micro-or-nanoparticles) on a substrate.

The present invention includes a method of providing a pattern of biological-binding areas for biological-testing, comprising: the creation of areas for metal nanoparticles on a substrate; patterning the selected areas by at least one process step selected from the group consisting of, exposing the areas of the material to an activating energy source (e.g. to reduce metal-oxide to a metal), baking a material at a temperature above the glass transition temperature (to coalesce reduced metal), etching the areas to expose metal nanoparticles from within the areas; and depositing patterned areas of biological-binding-glass on a substrate (to directly pattern the area, e.g. thermal evaporation or with nanoparticle containing micro-spheres); and attaching biological molecules to the selected areas (to provide binding sites for target molecules), such that the areas provide a chemistry for increased binding as compared to unselected areas. The metal particles may have a range of diameters; for example, with midpoint of the diameter range of less than about 300 nanometers in diameter. In addition, metal particles may be spaced from other metal particles by an average distance of at least one-half the midpoint of the diameter range. As noted above the present invention has shown a greatly enhanced sensitivity using defined areas of ceramic, bounded by glass, formed by the creation of spaced-apart metal nanoparticles with a subsequent bake and etch step.

Thus, the present invention provides a method for fabricating discrete patterns of biological-binding areas within areas which minimizes or exclude biological molecule binding depending on the initial biomolecule concentration used to coat the surface. The patterned biological-binding areas greatly enhanced biological molecule binding by fabricating areas which contain metal nanoparticles on and within a substrate. Biological molecules attached to the defined areas of ceramic, bounded by glass, formed by spaced-apart metal nanoparticles with a subsequent bake and etch step, which provide a chemistry for increased biological molecule binding.

The present invention includes distinct binding and non-binding regions of any shape and size, from 310 nm up to any desired size. In addition, the present invention may be used for SEF, SERS, SPR, SEERS. In addition, the imbedded nanoparticles of the present invention may be translated into other materials such as sol-gels, zeolites, hydrogels, and other glass or product formulations. The skilled artisan will recognize that common deposition techniques may be used in the present invention, e.g., CVD, electron beam, and so forth. In addition, the particles may be incorporated into common chromatography devices, such as microarrays, microfluidic channels, and chromatography columns.

In some embodiments, the biological-binding-organic contains at least one non-binding electron pair, or uses ionic bonds, hydrophobic, hydrophilic, van der Waals forces, and hydrogen bonds to bind to the surface. In some embodiments, the metal particles are used for assay techniques which incorporate plasmon excitation of proximal noble metal clusters, and the metal particles used for, but not limited to, surface enhanced fluorescence (SEF), surface enhanced Raman scattering (SERS), and surface plasmon resonance (SPR).

The present invention uses a glass of the above type and showed a surprising sensitivity to ultraviolet light exposure of over three times that of the commercially available photosensitive glass. The difference between the glass of the present invention and the commercially available photosensitive glass are also shown by improvement in the etch rate (a surprising over six times faster etch rate) and improved etch ratio (the glass of the present invention had etch ratios of exposed portions to that of the unexposed portion of at least 40:1 to 50:1, while the best reported etch ratios of the commercially available photosensitive glasses are 30:1 or less). One reason might be that the lower exposure leads to less light scattering into the side walls, and thus less etching of the side walls. The preferred composition modifications of adding boron oxide and reducing the silica content (possibly decreasing the glass's susceptibility to etching with HF acid) might be leading to boron silicate formation that enhances crystallization, but in any case, these etching results are surprising. Again, such an etching can, for example, expose more surface area on a glass slide and/or direct light more efficiently to and/or from a particular area within a pattern of biological-binding areas.

In this specification, inventive concepts may be disclosed in the context of assay plates (e.g., preferred electrode configurations, electrode materials, laminar structures, means for making electrical contacts to an electrode from the bottom of a plate, apparatuses and methods for measuring electrode induced luminescence (preferably electrochemiluminescence)), however, the concepts are also applicable to embodiments relating to other types of assay modules. The embodiments of the invention relate to assay modules, assay plates, having a plurality of assay wells (e.g., “multi-well plates” or “titer plates”). Apparatus of the present invention are designed to operate with the multi-well assay modules and generally incorporates features for inducing and measuring electrode induced luminescence probes, windows, and other analytical probes. The multi-well assay modules and apparatus of the present invention greatly improve among other things the speed, efficiency, quality, ease and cost of luminescence, particularly electrode induced luminescence, more particularly electrochemiluminescence, measurements.

The multi-well assay modules of the invention enable the performance of electrode induced luminescence-based assays inside one or more wells or chambers of a multi-well assay module (e.g., the wells of a multi-well assay plate). Multi-well assay plates may include several elements including, for example, a first layer, a substrate, wells, working electrodes, counter electrodes, reference electrodes, dielectric materials, contact surfaces for electrical connections, conductive through-holes electrically connecting the electrodes and contact surfaces, adhesives, assay reagents, and identifying markings or labels. The wells of the plates may be defined by holes in the first layer; the walls of the holes in the first layer may define the walls of the well. The substrate can be affixed to the first layer (either directly or in combination with other components) and can serve as the bottom of the well.

The multi-well assay modules (e.g., plates) may have any number of wells and/or chambers of any size or shape, arranged in any pattern or configuration, and be composed of a variety of different materials. One embodiment of the present invention includes multi-well assay plates that use industry standard multi-well plate formats for the number, size, shape and configuration of the plate and wells. Examples of standard formats include 96-, 384-, 1536-9600-, 10,000-, 20,000-, 30,000-, 40,000-, 50,000-, 60,000-, 70,000-, 80,000-, 90,000-, and 100,000-, 200,000-, 300,000-, 400,000-, 500,000-, 600,000-, 700,000-, 800,000-, 900,000-, 1,000,000-, or more well plates, with the wells configured in two-dimensional arrays. The numbers of wells may be any number of wells between 2 and 100,000 or 1,000,000 or more on a standard size plate. The skilled artisan will recognize that the actual number of wells may be any number between 1 and 1,000,000 or more, e.g., 9,876,543 well may be on a plate. Some wells have at least one first electrode incorporated therein, and some include at least one second electrode, i.e. at least one working electrode and at least one counter electrode. According to a particularly preferred embodiment, working, counter and, optionally, reference electrodes are incorporated into the wells and/or chambers. The assay plates are flat, but may also be curved (not flat).

The present invention provides a range of values for illustration and is not meant to limit the actual values, e.g., 1, 2, 3, 4, 5, 6, 7, 8, 9, 10, 15, 20, 25, 50, 100, 200, 300, 400, 500, 1000, 2000, 3000, 4000, 5000, 10,000, 20,000, 30,000, 40,000, 50,000, 100,000 or more, the numerical range is meant for illustration purposes and the skilled artisan will understand that the values within the range are contemplated by the inventors, e.g., 27, 349, 762, 1256, 2948, 5001, 7004, 9407, 12463, 45375 and so on.

The present invention addresses the problems associated with conventional titer plates by providing micro-posts or micro-Needles that can be used to couple cells and a variety of biomolecules such as, DNA, RNA, PNA, lipids, carbohydrates, ligands, receptors, pharmaceuticals, antigens, allergens, cells, antibodies, peptides, proteins, polymers, monomers, histones, other biomolecules, synthetic molecules and/or complexes for high throughput screening assays for drug discovery and much more. In the present invention, molecules or cells are immobilized to the tips of the micro-posts or micro-Needles and then transferred to Nano-titer plates and NanoArrays for additional solutions for analysis such as detection antibodies or other types of active agents. After exposure in the Nano-titer and NanoArray wells to the compounds of interest the posts with the attached cells or molecules are removed and washed in high volume solutions such as buffers. The micro-posts or micro-Needles of the present invention can be rapidly and effectively washed and transferred to high well density platforms. In this example, it is easier to wash microposts than it is to aspirate and remove fluid from small density wells where surface tension can become very high. This allows for rapid washing of cells and other biological or chemicals molecules used in assays for HTS.

The present invention provides a substrate that creates high surface areas that are capable of directly binding a wide variety of biomolecules without the use of hybridizing reagents. The present invention also provides the ability to immobilize hybridizing reagents directly to the substrate, which can then be used to immobilize the biomolecules of interest, e.g., molecules or complexes such as, DNA, RNA, PNA, lipids, carbohydrates, ligands, receptors, pharmaceuticals, antigens, allergens, cells, antibodies, peptides, proteins, polymers, monomers, histones, other biomolecules, synthetic molecules and/or complexes.

The present invention provides a multi-well plate having a first layer at least partially disposed on the substrate and one or more nano-wells that extends through the first layer that extends toward the substrate, wherein the one or more nano-wells comprising an opening in the first layer connected to bottom layer by one or more walls.

The multi-well plate includes between 1 and 1,000,000 or more nano-wells, e.g., each of the one or more nano-wells are between about 150 microns and 1000 microns with straight walls, tapered walls, curved walls, textured walls, smooth walls or a combination thereof and each of the one or more micro-posts or micro-Needles are between about 25 and 500 microns. In some embodiments a micro-post or micro-Needle is positioned in the nano-well at least partially seal the nano-well from the environment or may extend downwardly from a separate substrate to dispense a fluid or aspirate a fluid into at least one of the one or more of the nano-wells. Each well, micro-post or micro-Needle may have an agent binding surface on at least a portion of the bottom layer to bind one or more agents. The multi-well plate may also include at least a first electrode position within each of the one or more nano-wells, wherein the at least a first electrode is selected from a working electrode, a reference electrode, or a counter electrode, e.g., a first electrode position in the substrate at a first depth and a second electrode positioned orthogonally to the first electrode at a second depth.

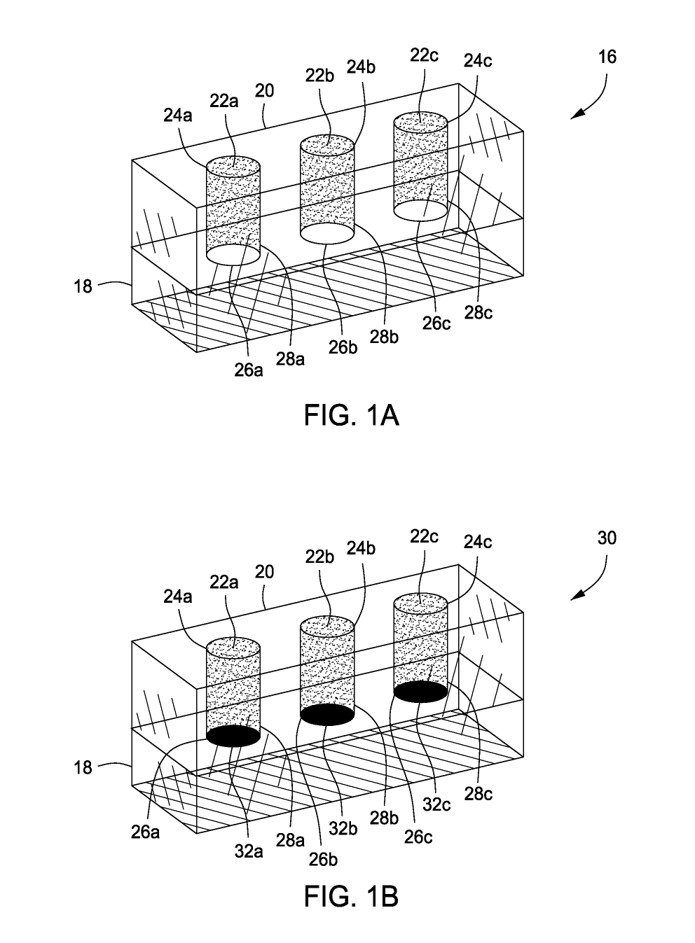

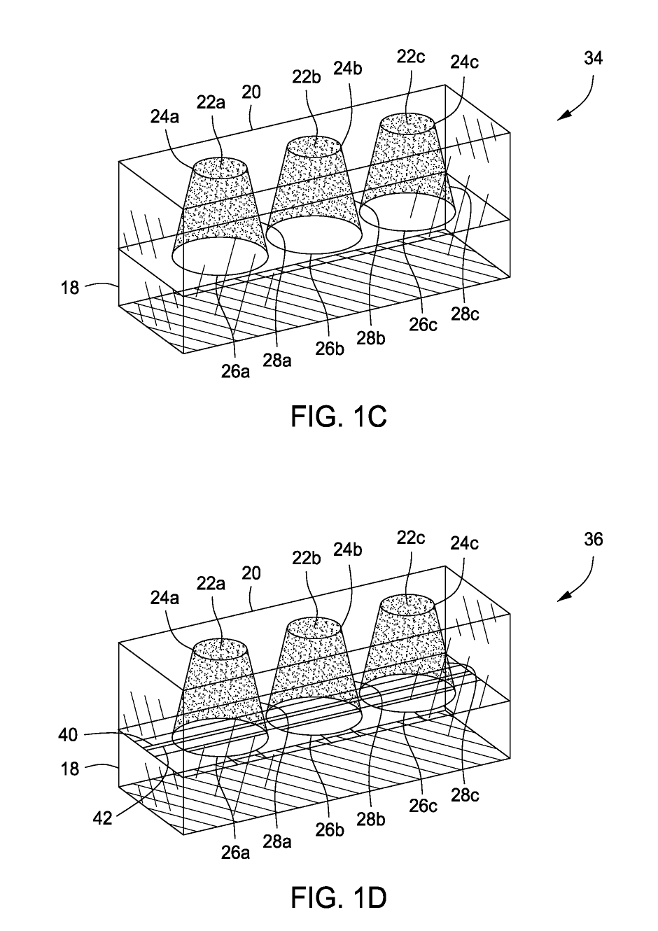

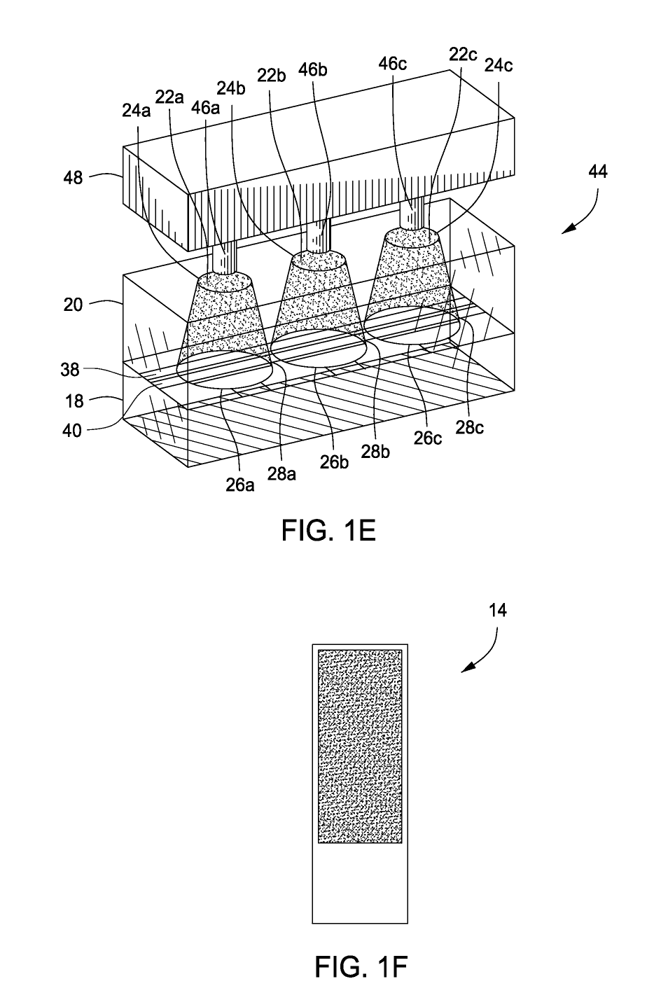

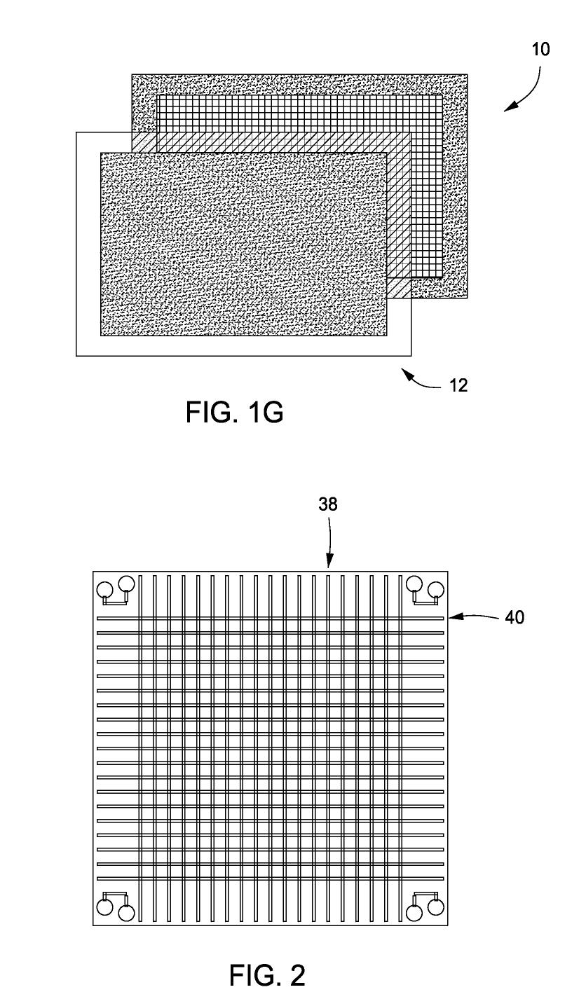

FIG. 1 is a schematic representing the various approaches to microfabricating nano-titer plates of the present invention. The present invention may be formed from/into any suitable structure to enable its use on specific instruments and applications including cuvettes, slides, plates and so forth. For example, the present invention may be formed into standard 1536 well micro-titer plates 10, 43,008 well nano-titer plates 12, microscope slides 14 with nano, micro or standard size wells. In addition, various combinations of these different size wells may be used. For example, a single titer plate may include a combination of nano sized wells, micro sized wells and/or standard sized wells. In addition, the present invention provides a variety of different cells configured (e.g., length, width, depth, opening size, shape, and wall angle and shape) for specific applications. For example, the present invention provides straight wall profiles for hyper-dense nano-titer wells for various optical applications, e.g., ECL, FRET, sandwich ELISA, and so forth.

FIG. 1A is an image of three straight walled wells of a titer plate. The straight wall profile 16 includes a substrate layer 18 having a first layer 20 positioned at least partially on the substrate layer 18. FIG. 1A shows three wells for illustration purposes, wells 22a, 22b and 22c extend through the first layer 20 to the substrate layer 18. The wells 22a, 22b and 22c are generally circular in shape having a generally circular opening 24a, 24b and 24c and generally circular bottom 26a, 26b and 26c connected by generally perpendicular walls 28a, 28b and 28c respectively. However, the skilled artisan will recognize that the size and shape of the well may vary by changing the opening 24, bottom 26 and/or walls 28, e.g., oval square, rectangular, triangular, free formed, polygonal or a combination thereof.

FIG. 1B is an image of three wells of a titer plate, where the wells have straight walls and an agent binding surface at bottom of each well. The straight wall profile 30 includes an agent binding surface 32a, 32b and 32c at bottom of the wells 22a, 22b and 22c. FIG. 1A shows three wells for illustration purposes, wells 22a, 22b and 22c extend through a first layer 20 to a substrate layer 18. The wells 22a, 22b and 22c are generally circular in shape having a generally circular opening 24a, 24b and 24c and generally circular bottom 26a, 26b and 26c connected by generally perpendicular walls 28a, 28b and 28c. However, the skilled artisan will recognize that the size and shape of the well may vary by changing the opening 24, bottom 26 and/or walls 28, e.g., oval, square, rectangular, triangular, free formed, polygonal or a combination thereof. At least a portion of the wells 22a, 22b and 22c includes an agent binding surface 32a, 32b and 32c. The agent binding surface 32a, 32b and 32c may be uniformed, random, patterned, or a combination thereof about the well surface. In some embodiments, the walls 28a, 28b and 28c of wells 22a, 22b and 22c may include one or more regions of agent binding surface. Although the agent binding surface 32a, 32b and 32c are shown at bottom of wells 22a, 22b and 22c the skilled artisan will recognize that the agent binding surface 32a, 32b and 32c may be on other locations in wells 22a, 22b and 22c.

FIG. 1C is an image of three wells of a titer plate, where the wells have inverted conical shaped walls. One application of the inverted conical shaped walls is cell-based assays due to the high well bottom surface. The inverted conical wall profile 34 has an inverted cone shape to reduce evaporation and increase consistent assay coefficients of variation (CV). FIG. 1C shows three wells for illustration purposes, wells 22a, 22b and 22c extend through the first layer 20 to the substrate layer 18. The wells 22a, 22b and 22c are generally circular in shape having a generally circular opening 24a, 24b and 24c and generally circular bottom 26a, 26b and 26c connected by walls 28a, 28b and 28c. The generally circular bottom 26a, 26b and 26c has a greater diameter than the corresponding generally circular opening 24a, 24b and 24c to provide a generally tapered profile resulting in a cone shape to form inverted conical shape wells 22a, 22b and 22c. The different diameters of the generally circular opening 24a, 24b and 24c and the generally circular bottom 26a, 26b and 26c giving the wall 28a, 28b and 28c a generally tapered profile resulting that results in inverted cone shaped wells 22a, 22b and 22c. However, the skilled artisan will recognize that the size and shape of the well may vary by changing the opening 24, bottom 26 and/or walls 28, e.g., oval square, rectangular, triangular, free formed, polygonal or a combination thereof. In addition, the shape of the wells 22a, 22b and 22c may be altered by changing the diameter of the generally circular bottom 26a, 26b and 26c relative to the generally circular opening 24a, 24b and 24c.

The present invention also provides a titer plate having inverted conical shaped and includes an agent binding surface at bottom of the well. The inverted conical wall profile (not shown) has an inverted cone shape to reduce evaporation and increase CVs. For example, the wells (not shown) extend through the first layer (not shown) to the substrate layer (not shown). The wells (not shown) are generally circular in shape having a generally circular opening (not shown) and generally circular bottom (not shown) connected by walls (not shown). The generally circular bottom (not shown) has a greater diameter than the generally circular opening (not shown) to provide a generally tapered profile resulting in a cone shape to form inverted conical shape wells (not shown). The generally circular bottom (not shown) may include one or more regions of agent binding surface (not shown). The agent binding surface (not shown) may be on the bottom, sides or other locations. However, the skilled artisan will recognize that the size and shape of the well may vary by changing the opening (not shown), bottom (not shown) and/or walls (not shown), e.g., oval, square, rectangular, triangular, free formed, polygonal or a combination thereof.

FIG. 1D is an image of three wells of a titer plate, where the wells have inverted conical shaped walls and one or more electrodes at bottom of each well. The inverted conical wall profile 36 has an inverted cone shape to reduce evaporation and increase consistent assay coefficients of variation (CV). FIG. 1D shows three wells for illustration purposes, wells 22a, 22b and 22c extend through the first layer 20 to the substrate layer 18. The wells 22a, 22b and 22c are generally circular in shape having a generally circular opening 24a, 24b and 24c and generally circular bottom 26a, 26b and 26c connected by walls 28a, 28b and 28c respectively. The generally circular bottom 26a, 26b and 26c has a greater diameter than the generally circular opening 24a, 24b and 24c to provide a generally tapered profile resulting in a cone shape to form inverted conical shape wells 22a, 22b and 22c. However, the skilled artisan will recognize that the size and shape of the well may vary by changing the opening 24, bottom 26 and/or walls 28, e.g., oval, square, rectangular, triangular, free formed, polygonal or a combination thereof. The generally circular bottom 26a, 26b and 26c of each well 22a, 22b and 22c includes two electrodes 40 and 42 that are on or in the first layer 20 or the substrate layer 18 such that the electrodes are at the generally circular bottom 26a, 26b and 26c and extend through wells 22a, 22b and 22c. The two electrodes 40 and 42 may be connected and/or isolated in various configurations known to the skilled artisan.

FIG. 1E is an image of three wells of a titer plate, where each of the wells have inverted conical shaped walls, one or more electrodes at bottom of the well and a micro-post well cover. FIG. 1E shows three wells for illustration purposes, wells 22a, 22b and 22c extend through the first layer 20 to the substrate layer 18. The wells 22a, 22b and 22c are generally circular in shape having generally circular openings 24a, 24b and 24c and generally circular bottoms 26a, 26b and 26c connected by walls 28a, 28b and 28c respectively. The generally circular bottoms 26a, 26b and 26c have a greater diameter than the generally circular openings 24a, 24b and 24c to provide a generally tapered profile resulting in inverted conical shape wells 22a, 22b and 22c. However, the skilled artisan will recognize that the size and shape of the wells 22a, 22b and 22c may vary by changing size, shape, length, diameter, etc. of the opening 24, bottom 26 and/or walls 28, e.g., oval, square, rectangular, triangular, free formed, polygonal or a combination thereof. The inverted conical wall profile 36 also has two electrodes 38 and 40 at the generally circular bottom 26a, 26b and 26c. The generally circular bottom 26a, 26b and 26c of each well 22a, 22b and 22c includes two electrodes 40 and 42 that are on/in the generally circular bottom 26a, 26b and 26c and extend through wells 22a, 22b and 22c. The two electrodes 40 and 42 may be connected and/or isolated in various configurations known to the skilled artisan.

The micro-post well cover 48 includes micro-posts or micro-Needles 46a, 46b and 46c that can be at least partially inserted into the wells 22a, 22b and 22c. The micro-posts or micro-Needles 46a, 46b and 46c are located on or about the micro-post well cover 48. The micro-posts or micro-Needles 46a, 46b, and 46c can be used to deliver an agent (not shown) to the wells 22a, 22b and 22c or can be used to contact an additional electrode, sample or agent (not shown) for sample analysis. In addition, the micro-posts or micro-Needles 46a, 46b and 46c may be solid, porous, hollow, perforated, slotted, or combination thereof.

FIGS. 1F and 1G are images of titer plates containing nano-wells of the present invention. FIG. 1G illustrates the present invention formed into standard 1536 well micro-titer plate 10 and a 43,008 well nano-titer plate 12. FIG. 1F shows microscope slides 14 with nano, micro or standard size wells.

FIG. 2 is a schematic of a top-down view of orthogonal isolated electrodes for electro-analysis and electro-technique activities. The present invention provides a first electrode 38 at a higher elevation in the substrate or first layer where the columns of electrodes rest on top of a dielectric insulator and rows of electrode 40 at a low elevation in the substrate or first layer. This allows replication one more time for the creation of a reference electrode. Additionally, the inside wall of the nano-well may be coated with a reference electrode material, such as silver, or micro-posts or micro-Needles may be placed into the solution to act as the reference material. The present invention provides a variety of electroanalytical techniques including: impedance measurements, polarography, potentiometry, cyclic voltammetry, amperometric analysis, conductance analysis.

Electrodes may be microfabricated into the bottom of each well and used for electrochemical analysis. For electrochemical measurements, a minimum of two electrodes must be used (called the working and the counter) and three electrodes is preferred (working, counter, and reference electrodes). The working and counter electrodes may be made out of a conductive material such as metal, carbon, or doped diamond. The reference electrode may be any of a wide number of reference electrodes such as silver/silver-chloride, standard calomel electrode, etc. The arrangement of the electrodes may be completed using a variety of microfabrication approaches known to those skilled in the art. One approach is to microfabricate individual electrodes to each well.

To address this problem, a double layer approach may be more effective. In this approach a working electrode is laid out across an entire row of nano-wells. The electrode is a single wire. This single wire line is carried out for all rows. Second, a passivating layer, such as SiO₂ is thermally evaporated or plasma deposited over the entire chip. Third, portions of the passivating layer that match up to the bottom of the nanowells are removed, exposing a small portion of the underlying electrode. Fourth, columns of a second electrode material are arrayed orthogonal to the underlying electrode. Last, the well portion of the nano-titer plate is adhered to the electrode portion using a variety of techniques (diffusion bonding, etc.).

Both of these lines are addressed using numerical or alphabetical values and correlate directly to a know pairings. For example 1-1 would refer to the upper left region and while only row 1 and column 1 electrodes were biased, they would only analyze location 1-1 due to the low electrical resistance (or the high electrical resistance seen outside of well that directly correlates with the desired electrode pair). This approach provides a simplified approach to addressing a significantly large number of analysis points using a significantly reduced electrical footprint.

Electrodes for non-analysis performance, i.e. cellular lysis, separation, dielectrophoresis, electroporation, and well cleaning. In addition to electroanalytical measurements, the electrodes may be used for non-analyte detection purposes. Common uses include cellular lysis using high frequency DC and AC input signals, separation of analytes or solution components using electrophoresis or dielectrophoresis, electroporation of cells with DNA, RNA, drugs, or other molecules, well cleaning using cyclic voltammetry to enable the reuseability of the wells, reducing costs, impedance spectroscopy of the solution. Impedance spectroscopy of the solution may be used to compare the relative conductivity of the nano-well solution, compared against standards, to identify beginning volume and ending volume. This calculation of solution evaporation would place a measurable control on evaporation leading to more accurate measurements, better identification of bad data, the establishment of assay controls when it comes to evaporation, among others.

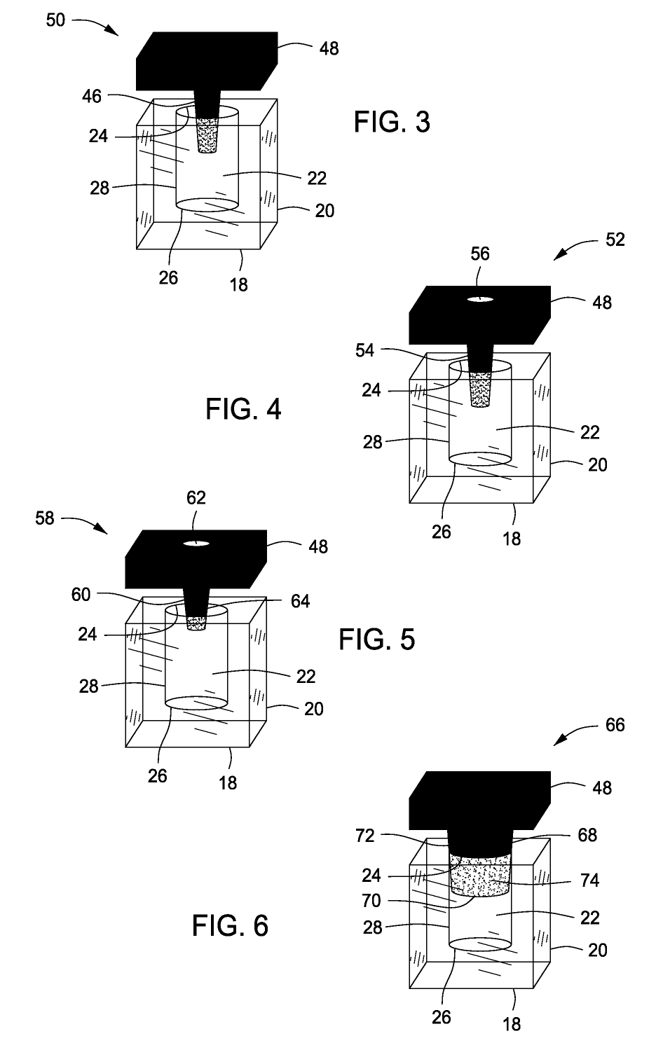

FIG. 3 is an image of a single well of a nano-titer plate or slide illustrating the use of a conductive micro-posts or micro-Needles for electro-analytical analysis, and/or cellular lysing. Similarly, to electrodes imbedded within the nano-titer plate well, individual micro-posts or micro-Needles or groups of micro-posts or micro-Needles may act as one or more electrodes. Construction of these micro-post electrodes includes coating one or more micro-posts or micro-needles with a metal coating tailored for each electrode. For example, the working and counter electrodes may wholly consist, or be coated with, a wide variety of conductive elements such as metals, conductive polymers, and various forms of carbon, among others; working electrodes may also be microfabricated using a variety of techniques, such as being coated with silver and further treated to create a silver/silver-chloride reference electrode. The micro-post-based electrodes may be used for electro-analytical techniques where measurements are made of biological relevance. Likewise, the micro-post-based electrodes may be used for non-analysis based sample preparation or measurements. The micro-posts or micro-Needles may be used to electroporate the cells for transfection with DNA or RNA molecules for genetic manipulation of the cells contained in the nanowells.

FIG. 3 illustrates a single straight wall well of a titer plate. The straight wall profile 50 includes a straight wall well 22 of a titer plate and a micro-post well cover 48. FIG. 3 shows a single well 22 for illustration purposes that extend through the first layer 20 to the substrate layer 18. The straight wall well 22 is generally circular in shape having a generally circular opening 24 and generally circular bottom 26 connected by a generally perpendicular wall 28. However, the skilled artisan will recognize that the size and shape of the well may vary by changing the opening 24, bottom 26 and/or walls 28, e.g., oval, square, rectangular, triangular, free formed, polygonal or a combination thereof. The micro-post well cover 48 includes one or more micro-posts or micro-Needles 46 that may be removably positioned at least partially in the straight wall well 22. The micro-post 46 may be solid, porous, biodegradable, perforated, or combination thereof. The length of the micro-post 46 may be varied depending on the application and the specific requirements.

FIG. 4 is an image of a single well of a titer plate or slide illustrating the use of an optically transparent micro-posts or micro-Needles for optical interrogation of fluid sample. The agent binding surface is an optical quality glass that can be used to create miniature lenses that can be placed within the wells of Nano-titer plates and nano-arrays for example APEX or ORACLE glass. These lenses would be capable of transmitting and collecting light in a system such as excitation light sources as well as emission sources. For example, sandwich enzyme linked immunosorbent assays that utilize fluorochrome labeled detection antibodies could be analyzed by passing the appropriate excitation wavelength from an external source such as a laser through the post into the Nano-titer plates and nano-arrays wells to excite the fluorochrome labeled detection antibody. The excitation light could then be turned off, and the light emitted from the fluorochrome could then be channeled back out of the micro-posts or micro-Needles for the determination of the amount of antibody present within the sample. In addition, enhanced chemiluminescent signal detection could be performed with the ECL product emitting light that is gathered by the post for analysis outside of the well. Furthermore, the posts could be turned into a lens for amplification of signal for detection or admission.

FIG. 4 illustrates a single straight wall well of a titer plate with an optically transparent micro-posts or micro-Needles for optical interrogation of fluid sample. FIG. 4 shows a single well 22 for illustration purposes that extend through the first layer 20 to the substrate layer 18. The straight wall profile 52 includes a straight wall well 22 of a titer plate and a micro-post well cover 48. The straight wall well 22 is generally circular in shape having a generally circular opening 24 and generally circular bottom 26 connected by generally perpendicular wall 28. However, the skilled artisan will recognize that the size and shape of the well may vary by changing the opening 24, bottom 26 and/or walls 28, e.g., oval, square, rectangular, triangular, free formed, polygonal or a combination thereof. The micro-post well cover 48 includes one or more optically transparent micro-posts or micro-Needles 54 that is optically transparent for optical interrogation of a sample. The length, diameter and shape of the optically transparent micro-post 54 may be varied depending on the application and the specific requirements. The optically transparent micro-post well cover 48 includes an optically transparent aperture 56 in communication with the optically transparent micro-post 54.

FIG. 5 is an image of a single well of a titer plate or slide illustrating the use of a hollow micro-post for fluid transfer into or out of a nano-well. The transferring of large collections of fluid samples that contain a variety of solutions such as libraries of small molecule drug candidates, proteins, receptors, cells, probe molecules (e.g., oligomers), and/or tissue samples stored in older style 96- or 384-well plates into more efficient high density arrays of microfluidic and nanofluidic receptacles such as a nanotiter plates or wells contained in a microscope format can consume one or more hours, during this time the samples may undergo significant evaporation, degrade or become contaminated. Therefore, a means to perform this transfer rapidly and efficiently may avoid many of the problems listed above.

A microfluidic volume of a variety of liquids may be loaded within a variety of receptacles by various means. One established method for transferring small liquid samples to a various surfaces or diluted into various liquids is by a variety of transfer pins loaded with the sample liquids. The present invention includes a method that delivers hundreds of spots in succession from one sample uptake, with delivery volumes between 0.05 mL to 2.5 mL.

In one embodiment, a micro-post may be used to deliver fluid to the nano-well or several micro-posts or micro-Needles, arrayed concentrically, may be used to deliver a much larger volume as the captured solution (to be delivered to the nano-wells) would occupy the volume between the micro-posts or micro-Needles as well as part of the volume outside the micro-post. The fluid may be delivered by printing the micro-post dropper to nano-wells with a greater hydrophilicity than the posts.

FIG. 5 illustrates a single straight wall well of a titer plate with a hollow micro-post 60 for transferring a sample (not shown). FIG. 5 shows a single well 22 for illustration purposes that extend through the first layer 20 to the substrate layer 18. The straight wall profile 58 includes a straight wall well 22 of a titer plate and a micro-post well cover 48. The straight wall well 22 is generally circular in shape having a generally circular opening 24 and generally circular bottom 26 connected by generally perpendicular wall 28. However, the skilled artisan will recognize that the size and shape of the well may vary by changing the opening 24, bottom 26 and/or walls 28, e.g., oval, square, rectangular, triangular, free formed, polygonal or a combination thereof. The micro-post well cover 48 includes one or more hollow micro-posts or micro-Needles 60 that is capable of transferring a substance from a reservoir to the straight wall well 22. The micro-post well cover 48 includes a micro-post aperture 62 connected to micro-post channel 64 that extends through the hollow micro-posts or micro-Needles 60. The length, diameter and shape of the hollow micro-post 60 may be varied depending on the application and the specific requirements.

FIG. 6 is an image of a single straight wall nano-well of a titer plate with a micro-posts or micro-Needles used to hermetically seal nano-well to eliminate evaporation, leading to lower CVs. The micro-posts or micro-Needles of the present invention may be microfabricated a variety of ways including micro-injection molding, hot embossing, and casting. These pliable micro-posts or micro-Needles may be used as seals, once placed into the nano-wells. Their pliability would ensure that the union between the micro-posts or micro-Needles and the nano-well was fluid tight.

FIG. 6 shows a single well 22 for illustration purposes that extend through the first layer 20 to the substrate layer 18. The straight wall profile 66 includes a straight wall nano-well 22 of a titer plate and a micro-post well cover 48. The straight wall nano-well 22 is generally circular in shape having a generally circular opening 24 and generally circular bottom 26 connected by generally perpendicular wall 28. However, the skilled artisan will recognize that the size and shape of the well may vary by changing the opening 24, bottom 26 and/or walls 28, e.g., oval, square, rectangular, triangular, free formed, polygonal or a combination thereof. The micro-post well cover 48 includes one or more micro-posts or micro-Needles plugs 68 that may be removably positioned at least partially within the well 22 to seal the nano-well to eliminate evaporation. The micro-posts or micro-Needles plugs 68 has a first end 70 and a base 72 with the diameter of the base 72 being larger than the diameter of the first end 70 such that the walls 74 are tapered from the base 72 to the first end 70. As the micro-posts or micro-Needles plugs 68 is positioned into the straight wall nano-well 22 the first end 70 extends into the nano-well 22. The micro-posts or micro-Needles plugs 68 extends to the tapered walls 74 contact the generally circular opening 24 to hermetically seal the nano-well 22. However, the skilled artisan will recognize that the shape of the well may vary, e.g., oval square, rectangular, triangular, free formed, polygonal or a combination thereof, and the walls may be concave, convex, tapered, straight, textured, smooth or a combination thereof.

In one embodiment, the substrate (e.g. APEX) glass is processed in a variety of methods to create different sidewall topographies and angles. Straight wall topographies may be created by exposing the glass to optimal UV exposure. Flared side wall angles may be easily created by over exposing the substrate (e.g. APEX) material. Additionally, side walls may be created to be either optically smooth, or roughened, in which they are rougher and scatter incoming light.

Wells that have smaller openings exposed to air, with respect to base dimensions, have two advantages. First, the small surface area exposed to air, with respect to total volume, will slow down evaporation of well solution, leading to more consistent assay coefficients of variation (CV). This ultimately leads to more accurate and predictable results in a variety of research fields such as drug development. Second, nano-titer plate wells that have a larger base (at the bottom of the nano-well) area with respect to top surface (exposed to air) provides a large surface area for the immobilization of a critical number of cells (typically around 200) for in vivo assays, while keeping well volume as little as possible. The small well volume requires less therapeutic to be used during the assay, translating to lower costs per assay.

The nano-titer plate may be microfabricated using a variety of approaches obvious to those skilled in the art. A typical approach includes microfabricating the top (portion of the part, e.g., which contains the wells) and the bottom (the solid structure under the wells) and joining them using a variety of techniques such as diffusion bonding or thermal bonding. Similarly, the wells may be made out of one monolithic structure where well depth is controlled by etch time and acid concentration.

The substrate (e.g. ORACLE glass) offers the ability to create high surface areas that are capable of directly binding a wide variety of biomolecules without the use of hybridizing reagents. In addition, hybridizing reagents can be immobilized to the bottom of the well, which then can be used to immobilize the biomolecules of interest molecules or complexes, e.g., DNA, RNA, PNA, lipids, carbohydrates, ligands, receptors, pharmaceuticals, antigens, allergens, cells, antibodies, peptides, proteins, polymers, monomers, histones, other biomolecules, synthetic molecules and/or complexes.

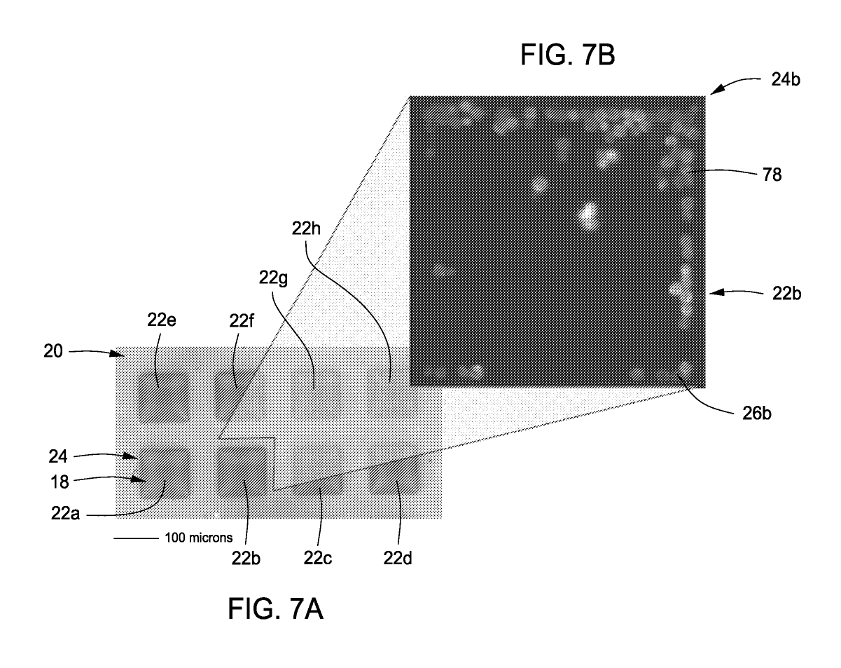

FIG. 7A is an image of a nano-titer plate capture of live S. cerevisiae. The present invention provides a nano-titer plate 76 having eight wells for illustration purposes, wells 22a-22h that extend through the first layer 20 to the substrate layer 18. Each well 22a-22h includes a generally rectangular opening 24a-24h respectively and corresponding generally rectangular bottom (not shown) connected by generally perpendicular wall (not shown). Each well 22a-22h is a 100 micron square having a generally rectangular opening 24a-24h and a generally rectangular bottom (not shown) that is a 100 micron square. The well 22a-22h are capable of binding live S. cerevisiae. FIG. 7B is an image of a nano-titer plate capture of live S. cerevisiae fluorescing with green fluorescent protein. Well 22b is shown and includes a generally rectangular opening 24b and generally rectangular bottom 26b. FIG. 7B shows live S. cerevisiae within the well 22b fluorescing with green fluorescent protein 78.

The present invention also provides a micro-post lenses for uses with a CCD camera for detection. The micro-posts or micro-Needles of the present invention are microfabricated out of a high quality optical glass substrate. The glass substrate is transparent in the relevant regions of the electromagnetic spectrum and allows its use with other optics including cameras including CCD cameras. Additionally, the micro-posts or micro-Needles of the present invention may be placed into individual nano-wells and used to pass excitation lights and/or be used to capture emissions. The micro-posts or micro-Needles of the present invention may also act as lenses.

In one embodiment excitation light may be supplied from the top or bottom of the micro-post and emission light may be captured via the stalk/shaft of the micro-post. To record the captured emitted light the backside of the micro-post may be directly affixed to a CCD camera where individual pixels would line up with individual micro-posts or micro-Needles, eliminating a significant amount computational error associated with light scatter.

In another embodiment, an optical window (e.g., bandgap/narrowpass/longpass filter) may be placed between the micro-post patch and the CCD chip. The optical windows may be a separate glass layer or they may be coated directly to the CCD chip or the micro-post patch. The micro-post may record fluorescence or chemiluminescence information from reactions occurring within the well or those that are directly immobilized onto the micro-post tip.

The present inventors recognized that protein analysis scanners currently used in the art require the sample be canned using a dry chip to avoid fouling the device with fluids. Traditional protein slides such as nitrocellulose are usually not compatible for doing ECL detection due to the generation of a luminescent substrate in a wet environment. The present invention provides nanoArrays for enhanced chemiluminescence (ECL) detection. The present invention provides substrate bindry surfaces (e.g. Oracle) in the wells and binding offer a solution to employ ECL technology for analysis for protein microarrays. In this fashion the ECL solution is pipetted into substrate bindry surfaces (e.g. Oracle) in the nanoarrays that contain true wells for containment of fluid, meaning ECL solution created in 1 well does not cross contaminate into another well. The wells can then be sealed apart using a microscope slide or micro-post that hermetically seal the wells apart. This embodiment provides an excellent method for low level detection of molecules due to the enzymatic generation of ECL product that gives off a light signal. The nanoArray that is now sealed can be used in most protein or DNA scanners.

The present invention provides lower CVs due to lower evaporation at small volumes due to conical shape. In addition, the present invention provides the ability to transfer and wash components on posts are surprisingly easy to accomplish. The present invention provides a high surface area for biological immobilization. The addition of a CCD on back of micro-posts or micro-Needles removes computational error associated with light scatter.

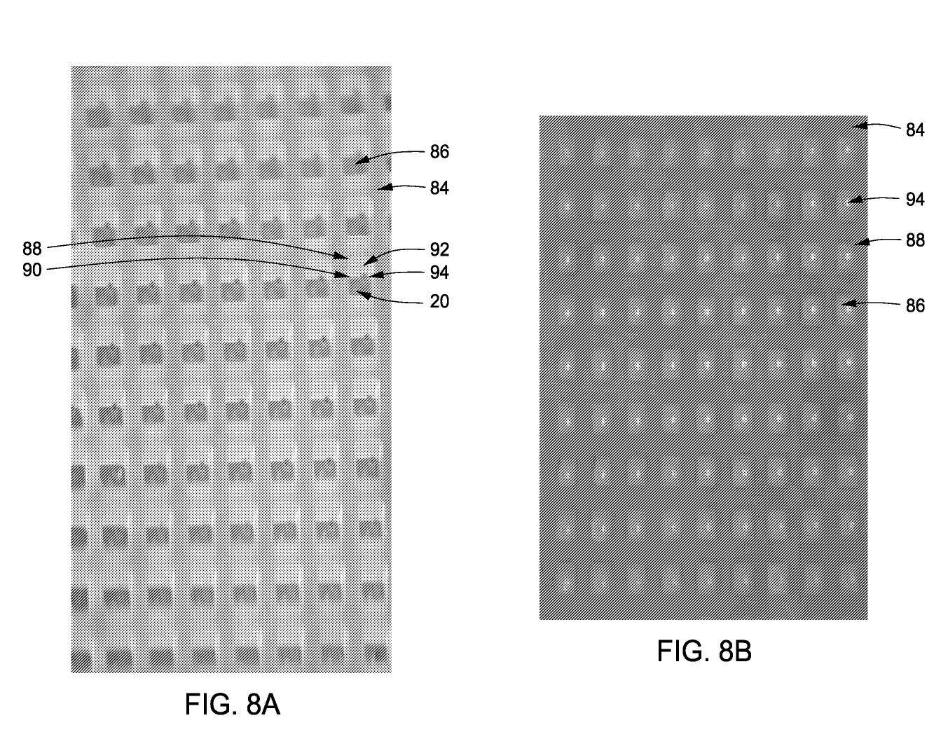

FIGS. 8A and 8B are images of a nano-titer plate including a micro-post within the nano-well. FIG. 8A is an image of a portion of a titer plate showing 70 nano-wells 80 having a micro-post 82 positioned within the nano-wells 80. Each nano-well 80 has a first layer 84 positioned at least partially on the substrate layer 86 with the nano-wells 80 extending through the first layer 84 to the substrate layer 86. The nano-wells 80 are generally circular in rectangular having a generally rectangular opening 88 and generally rectangular bottom 90 connected by generally perpendicular walls 92 respectively. However, the skilled artisan will recognize that the size and shape of the well may vary by changing the opening, bottom and/or walls, e.g., oval square, rectangular, triangular, free formed, polygonal or a combination thereof.

The nano-wells 80 include a micro-post 94 positioned within the nano-wells 80. The exact location of the micro-post 94 may be varied depending on the specific application. FIG. 8A illustrates 250 micron squares separated by 100 micron spacing and a 50 micron micro-post aligned to form 90 nano-liter nano-wells.

FIG. 8B is an image illustrating the optically transparent micro-post within the nano-wells of a portion of a titer plate showing 70 nano-wells 80 having a micro-post 82 positioned within the nano-wells 80. Each nano-well 80 has a first layer 84 positioned at least partially on the substrate layer 86 with the nano-wells 80 extending through the first layer 84 to the substrate layer 86. The nano-wells 80 are generally circular in rectangular having a generally rectangular opening 88 and generally rectangular bottom 90 connected by generally perpendicular walls 92 respectively. However, the skilled artisan will recognize that the size and shape of the well may vary by changing the opening, bottom and/or walls, e.g., oval square, rectangular, triangular, free formed, polygonal or a combination thereof.

The nano-wells 80 include a micro-post 94 positioned within the nano-wells 80. The exact location of the micro-post 94 may be varied depending on the specific application. FIG. 8A illustrates 250 micron squares separated by 100 micron spacing and a 50 micron micro-post aligned to form 90 nano-liter nano-wells.

One or more metal coatings may be applied to the bottom or the walls of the well and/or the micro-post, when present. The coating may entirely cover the surface and the coating on different surfaces or wells need not be the same. Coating materials include silver, gold, platinum, rhodium, palladium, nickel, cobalt, copper, or their alloys.

The metal nanoparticles are at least one of silver, gold, platinum, rhodium, palladium, nickel, cobalt, copper, or their alloys. In some embodiments, the biological-binding-areas are of a glass containing oxide of at least one of silver, gold, and copper, and wherein at least some of the oxide of at least one of silver, gold, and copper is reduced to metal to provide the metal nanoparticles. In some embodiments, the metal particles that are exposed from within the glass are formed by metal-precipitating and then metal-coalescing baking. In some embodiments, the areas are exposed by patterned high-energy particles (including UV light) to reduce at least some of the oxide of at least one of silver, gold, and copper in the areas to metal.

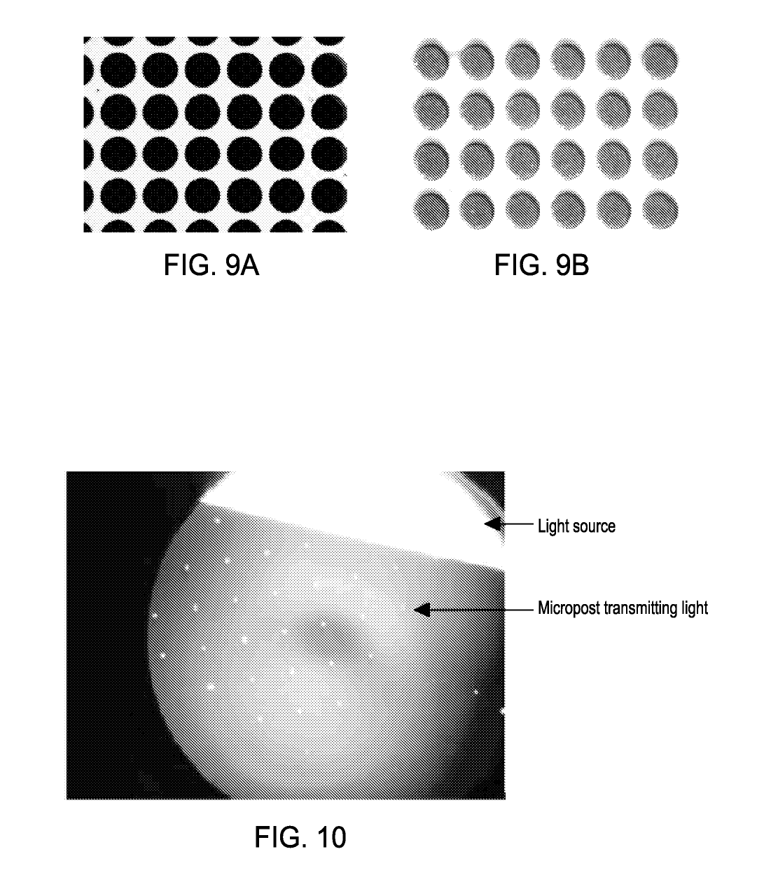

In some embodiments, unetched biological binding areas are used as seen in FIG. 9A. Etching is used in other embodiments to remove glass to glass-ceramic to expose more surface area of nanoparticles as seen in FIG. 9B. Etching can also, for example, expose more surface area for biomolecule binding on a glass slide or surface and/or direct light more efficiently to and/or from a particular area within a pattern of biological areas. Thus the effect would be to tailor the surface area for high binding densities in each individual biological binding location. For example, the topography roughly the same in every binding area no matter how rough or smooth it is desired to be. This repeatable area would create approximately the same high binding densities in the each well.

In some embodiments, at least one metal-coalescing baking step is done on glass micro-spheres, prior to screen printing of the glass micro-spheres on a substrate (e.g. with a sol-gel binder). In some embodiments, a surface activation etching after deposition on the substrate (alternatively in some cases, it is not used, and in still other cases it is used prior to deposition). In some embodiments, the metal particles are added as metal particles during fabrication of the biological-binding-material, rather than the currently generally preferred method of being reduced from an oxide or a salt. In some embodiments, the metal particles are added as metal salt during fabrication of biological-binding-glass. Further, in some embodiments, the matrix containing the metal particles is a non-glass (although still preferably transparent or translucent). In some embodiments, the micro-spheres are between 1 and 1,000,000 nanometers in diameter. In some embodiments, the metal particles are between 1 and 300 nanometers in diameter. In some embodiments, at least half the metal particles are 1-500 nanometers in diameter and spaced from other metal particles by an average distance of at least 2 nanometers. In some embodiments, at least half the metal particles are 1-500 nanometers in diameter and spaced from other metal particles by an average distance of at least 20 nanometers.

FIG. 10 is an image of a light based assay having posts extending from the surface of the substrate. The posts (in this case micro-posts) transmit light individually and not through the substrate in general. The posts have a light source individually illuminating the posts. Light is not transmitted through the glass background. This allows for optical transmission into the wells. In addition the combination of microposts and microneedles in combination with a nanowell can be made from plastic, ceramic, metal, resin, gel, glass, silicon, glass-ceramics and composites thereof. Please let me know what else is needed.

In some embodiments, photosensitive glass is used to create metal nanoparticles beads. For example, metal oxides (e.g. silver) may be selectively reduced from the glass and coalesced into nanoparticles. In some embodiments, the initial glass composition is of: 65-72% silica, at least 3% K2O with 6%-16% of a combination of K2O and Na2O, 0.15-5% of at least one oxide selected from the group consisting of Ag2O and Au2O, 0.75%-7% B2O3, and 6-7% Al2O3, with the combination of B2O3, and Al₂O₃ not exceeding 13%, 8-13% Li2O, and 0.014-0.1% CeO2. In some embodiments, the composition is: 35-72% silica, 3-16% K2O, 0.15-5% Ag2O, 0.75-13% B2O3, 8-13% Li2O, and 0.014-0.1% CeO2. In some embodiments, the composition is 46-72% silica, 3-16% K2O, 0.15-5% Ag2O, 0.75-13% B2O3, 6-7% Al₂O₃, 11-13% Li2O, and 0.014-0.1% CeO2. Preferably in the above embodiments the CeO2 is in the 0.04-0.1% range. In some embodiments, the glass substrate is heated to a temperature of 450-550° C. for between 10 minutes and 2 hours (e.g. 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0 hours or divisions thereof) and then heated to a temperature range heated to 550-650 C for between 10 minutes and 2 hours (e.g. 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0 hours or divisions thereof). Note the heat treatment tends to crystallize the photosensitive glass, and that the “glass” as referred to herein, may be at least partially crystallized.

In some embodiments the biological-testing includes testing of at least one of DNA, RNA, and other nucleic acid containing molecules, PNAs, Amino acids, lipids, fatty acids, histones, proteins, peptides, and other amino acid containing molecules. In some embodiments, the biological-binding-organic contains at least one non-binding electron pair. In some embodiments, the metal particles used for assay techniques using plasmon excitation of proximal noble metal clusters, and the metal particles used for SEF, SERS, SERRS, or SPR, or other related techniques.

As noted above, the glass beads can be processed to provide enhanced sensitivity for biological-testing as compared to conventional surface areas of metal (e.g. areas of silver wire). However, the glass beads may also be exposed and etched to direct light within the glass beads substrate, e.g. on the backside of a structure of patterned nanoparticles for directing interrogation light and/or directing fluorescence from a patterned biological-binding area. In addition, a process exposure and etched can be used with our glass composition, and Kravitz et al's U.S. Pat. No. 7,132,054 is hereby incorporated by reference.

Thus, photosensitive glass can be processed to provide enhanced sensitivity for biological-testing and for directing interrogation light and/or directing fluorescence from a patterned biological-binding area. Thus, the photosensitive glass may have patterned nanoparticles on one side and high precision etched structures on the other (although both could be on the same side).

The present invention may be used to selectively bind DNA, RNA, PNA, lipids, antibodies, proteins, enzymes, drugs, pro-drugs, receptors, ligands, analytes, cells, bacteriophages, cell components, molecular imprint antibodies, DNA-based aptamers, cyclodextrins, macromolecules, dendrimers or other biological or synthetic compound, complex or composition.

In addition the present invention may be used in conjunction with labels e.g., cresyl fast violet, cresyl blue violet, rhodamine-6G, para-aminobenzoic acid, phthalic acids, erythrosin or aminoacridine. In addition, fluorophore or fluorescent reporter groups may be used and include any compound, label, or moiety that absorbs energy, typically from an illumination source, to reach an electronically excited state, and then emits energy, typically at a characteristic wavelength, to achieve a lower energy state, e.g., fluorescein and its derivatives; rhodamine and its derivatives; cyanine and its derivatives; coumarin and its derivatives; Cascade Blue and its derivatives; Lucifer Yellow and its derivatives; BODIPY and its derivatives; and the like. Exemplary fluorophores include indocarbocyanine (C3), indodicarbocyanine (C5), Cy3, Cy3.5, Cy5, Cy5.5, Cy7, Texas Red, Pacific Blue, Oregon Green 488, Alexa Fluor 488, Alexa Fluor 532, Alexa Fluor 546, Alexa Fluor 568, Alexa Fluor 594, Alexa Fluor 647, Alexa Fluor 660, Alexa Fluor 680, JOE, Lissamine, Rhodamine Green, fluorescein isothiocyanate, carboxy-fluorescein, phycoerythrin, rhodamine, dichlororhodamine, carboxy tetramethylrhodamine, carboxy-X-rhodamine, PicoGreen, RiboGreen, and the like. Descriptions of fluorophores and their use, can be found in, among other places, R. Haugland, Handbook of Fluorescent Probes and Research Products, 9.sup.th ed. (2002), Molecular Probes, Eugene, Oreg.; M. Schena, Microarray Analysis (2003), John Wiley & Sons, Hoboken, N.J.; Synthetic Medicinal Chemistry 2003/2004 Catalog, Berry and Associates, Ann Arbor, Mich.; G. Hermanson, Bioconjugate Techniques, Academic Press (1996); and Glen Research 2002 Catalog, Sterling, Va. Near-infrared dyes are expressly within the intended meaning of the terms fluorophore and fluorescent reporter group.

The wells and micro-post may be used in conjunction with various methods of detecting. In certain embodiments, detecting includes near field microscopy, near-field scanning optical microscopy; far-field microscopy, far-field confocal microscopy and fluorescence correlation spectroscopy; wide-field epi-illumination microscopy, evanescent wave excitation microscopy or total internal reflectance (TIR) microscopy; scanning confocal fluorescence microscopy; the multiparameter fluorescence detection (MFD) technique; two-photon excitation microscopy; inverted optical microscope; or fluorescence excitation spectroscopy combined with shear-force microscopy.

In certain embodiments, detecting includes scanning probe microscopy techniques, applied optical spectroscopy techniques, nanoelectromechanical (NEMS) techniques, scanning tunneling microscopy; atomic force microscopy (AFM), cryo-AFM and single-walled carbon nanotube-AFM (SWNT-AFM); spectrally resolved fluorescence imaging microscopy (SFLIM); surface enhanced Raman spectroscopy (SERS); surface enhanced resonant Raman spectroscopy (SERRS); surface plasmon resonance (SPR); and scanning electrochemical microscopy (SECM).

The present invention provides a solid substrate which may contain additional surface functional groups such as carboxylates, esters, alcohols, carbamides, aldehydes, amines, sulfur oxides, nitrogen oxides, or halides, which may facilitate attachment of analytical reactants, cells, and/or particles-to bond to the solid support or other compositions bound to the solid support. One example of the attachments include Silane chemistry. Silane chemistry is a well known in the field and has applications as adhesion promoters, crosslinking agents, water scavengers, and coupling agents. Silanes are generally monomeric silicon compounds with four substituents groups attached to a silicon atom. The substituent groups can include almost any combination of nonreactive, inorganically reactive, or organically reactive groups. The basic or fundamental structure of silanes is RₙSi(OR)₄₋ₙ with organosilanes with “R” being an alkyl, aryl, or organofunctional group. Inorganic reactivity is formed from covalent bonds formed through oxygen to the silicon atom forming a siloxane bond. Organic reactivity occurs on the organic molecule which does not directly involve the silicon atom. The large combinations of function groups described herein illustrate silicon's versatility and its ability to be used in a variety of applications with carbon-based chemicals. For example, special characteristics for the silane chemistry can be tailored by adding non-reactive groups such as methyl or larger alkyl groups with phenyl groups. Examples of silane chemistries include but are not limited to organosilanes, aminosilanes, olefin containing silane, vinyl silanes, epoxy silanes, methacryl silanes, sulfur terminated silanes, phenyl silanes, and chlorosilanes. Silicon is a major constituent of glass ceramic materials. Silanes will bond covalently with glass ceramic surfaces fabricated within the instant invention. Sulfur terminated silanes, e.g., mercaptopropyltrimethoxysilane HS(CH₂)₃Si(OMe)₃. In addition, organosilanes may be used, e.g. aminosilanes: 3-aminopropyl triethoxysilane, 3-aminopropylmethyldiethoxysilane, 3-aminopropyl dimethylethoxysilane, 3-aminopropyl trimethoxysilane, N-(2-aminoethyl)-3-aminopropylmethyl dimethoxysilane, N-(2-aminoethyl-3-aminopropyl)trimethoxysilane, aminophenyl trimethoxysilane, 4-aminobutyldimethyl methoxysilane, 4-aminobutyltriethoxysilane, aminoethylaminomethylphenethyl trimethoxysilane and mixtures thereof. Similarly, vinyl silanes may be used, e.g., Vinyltriethoxysilane. Olefin containing silane may be used, e.g., olefin-containing silane selected from the group consisting of 3-(trimethoxysilyl)propyl methacrylate, N-[3-(trimethoxysilyl)propyl]-N′-(4-vinylbenzyl)ethylenediamine, triethoxyvinylsilane, triethylvinylsilane, vinyltrichlorosilane, vinyltrimethoxysilane, vinyltrimethylsilane, and mixtures thereof. Epoxy silanes may be used, e.g., (3-glycidoxypropyl)trimethoxysilane and Methacryl silanes may be used, e.g. 3-(trimethoxysilyl)propyl methacrylate. Phenyl silanes may be used, e.g., silylbenzene. Chlorosilanes like dimethyldichlorosilane may be used. The surface may be polymerized from olefin-containing monomer is selected from the group consisting of acrylic acid, methacrylic acid, vinylacetic acid, 4-vinylbenzoic acid, itaconic acid, allyl amine, allylethylamine, 4-aminostyrene, 2-aminoethyl methacrylate, acryloyl chloride, methacryloyl chloride, chlorostyrene, dichlorostyrene, 4-hydroxystyrene, hydroxymethylstyrene, vinylbenzyl alcohol, allyl alcohol, 2-hydroxyethyl methacrylate, poly(ethylene glycol)methacrylate, and mixtures thereof.

The solid support may be polymerized with a monomer selected from the group consisting of acrylic acid, acrylamide, methacrylic acid, vinylacetic acid, 4-vinylbenzoic acid, itaconic acid, allyl amine, allylethylamine, 4-aminostyrene, 2-aminoethyl methacrylate, acryloyl chloride, methacryloyl chloride, chlorostyrene, dichlorostyrene, 4-hydroxystyrene, hydroxymethyl styrene, vinylbenzyl alcohol, allyl alcohol, 2-hydroxyethyl methacrylate, poly(ethyleneglycol) methacrylate, and mixtures thereof, together with a monomer selected from the group consisting of acrylic acid, methacrylic acid, vinylacetic acid, 4-vinylbenzoic acid, itaconic acid, allyl amine, allylethylamine, 4-aminostyrene, 2-aminoethylmethacrylate, acryloyl chloride, methacryloyl chloride, chlorostyrene, dichlorostyrene, 4-hydroxystyrene, hydroxymethyl styrene, vinylbenzyl alcohol, allyl alcohol, 2-hydroxyethyl methacrylate, poly(ethylene glycol) methacrylate, methyl acrylate, methylmethacrylate, ethyl acrylate, ethyl methacrylate, styrene, 1-vinylimidazole, 2-vinylpyridine, 4-vinylpyridine, divinylbenzene, ethylene glycol dimethacrylate, N,N′-methylenediacrylamide, N,N′-phenylenediacrylamide, 3,5-bis(acryloylamido) benzoic acid, pentaerythritol triacrylate, trimethylolpropane trimethacrylate, pentaerytrithol tetraacrylate, trimethylolpropane ethoxylate (14/3 EO/OH) triacrylate, trimethylolpropane ethoxylate (7/3 EO/OH) triacrylate, trimethylolpropane propoxylate (1 PO/OH)triacrylate, trimethylolpropane propoxylate (2 PO/OH) triacrylate, and mixtures thereof.

It is contemplated that any embodiment discussed in this specification can be implemented with respect to any method, kit, reagent, or composition of the invention, and vice versa. Furthermore, compositions of the invention can be used to achieve methods of the invention.

In addition, the present invention may include combinations of metals and metal nanoparticles for molecule-affinity, e.g., high-biological molecule-affinity silver, gold, platinum, rhodium, palladium, cerium, nickel, cobalt, copper, or their alloys or combinations of these metals or alloys, or oxides of these elements. This includes the deposition of metals, alloys, semi-metalic or non-metalic compositions on to and into the compositions of the instant invention. This can be used to entirely cover, partially cover or selectively cover the compositions of the instant invention.

Furthermore, the present devices may be used in in vitro applications as well as in vivo applications, e.g., concentration determinations, detection of low abundant compounds, uses as a feedback control loop for medicines; uses as monitor of the heart for continued blood turnover, detection of compounds or compositions including large and small molecular weight compounds using FTIR, SERS, in vivo ELISAs, etc. In addition, both in vitro applications as well as in vivo applications can be surface modified (partially or entirely) by the addition of compositions, molecules, functional groups, ions, etc and specifically modifications using silane chemistry.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. An etched plate having one or more etched features comprising:
a substrate;
a first layer at least partially disposed on the substrate; and
one or more etched features that extends at least partially into the first layer toward the substrate, wherein the one or more etched features comprising an opening in the first layer connected to a bottom by one or more walls.

2. The etched plate of claim 1, wherein the one or more etched features extend through the first layer to locate the bottom in the substrate.

3. The etched plate of claim 1, further comprising one or more micro-posts or micro-needles positioned in the one or more etched features, wherein the one or more micro-posts or micro-needles seal the one or more etched features from the environment, partially seal the one or more etched features from the environment, or a combination thereof.

4. The etched plate of claim 1, further comprising one or more micro-posts or micro-needles extending downwardly from a second substrate toward the one or more etched features to dispense a fluid or aspirate a fluid into at least one of the one or more etched features.

5. The etched plate of claim 1, further comprising an agent binding surface on at least a portion of the one or more etched features to bind one or more agents selected from molecules, complexes, DNA, RNA, PNA, lipids, particles, nanoparticles, metal particles, surface functional groups, carboxylates, esters, alcohols, carbamides, aldehydes, amines, sulfur oxides, nitrogen oxides, halides, carbohydrates, ligands, receptors, pharmaceuticals, silanes, silanization groups, antigens, allergens, cells, antibodies, peptides, proteins, polymers, monomers, histones, other biomolecules, synthetic molecules or complexes.

6. The etched plate of claim 1, further comprising one or more micro-posts or micro-needles located about the one or more etched features each optionally comprising an agent binding surface to bind one or more agents selected from molecules, complexes, DNA, RNA, PNA, lipids, particles, nanoparticles, metal particles, surface functional groups, carboxylates, esters, alcohols, carbamides, aldehydes, amines, sulfur oxides, nitrogen oxides, halides, carbohydrates, ligands, receptors, pharmaceuticals, silanes, silanization groups, antigens, allergens, cells, antibodies, peptides, proteins, polymers, monomers, histones, other biomolecules, synthetic molecules or complexes, wherein the one or more micro-posts or micro-needles can contact the one or more etched features.

7. The etched plate of claim 1, further comprising one or more detection methods on a micro-post, a micro-needle, one of the one or more etched or combination thereof selected from antigen-antibody, antibody-antigen, Sandwich ELISA, aptamers, enzyme-substrate, receptor-ligand, protein-drug, protein-liposome, and antibody-carbohydrate, rolling circle amplification, radioisotope labeling, surface-enhanced laser desorption/ionization (SELDI) mass spectrometry, atomic force microscopy, surface plasmon resonance, planar waveguide, and electrochemical detection.

8. The etched plate of claim 1, wherein at least one of the one or more etched features further comprising at least a first electrode position within each of the one or more etched features, wherein the at least a first electrode is selected from a working electrode, a reference electrode, or a counter electrode.

9. The etched plate of claim 1, further comprising a first electrode position in the substrate at a first depth and a second electrode positioned in proximity to the first electrode at a second depth.

10. The etched plate of claim 1, further comprising an electrode located on one or more micro-posts for insertion into one or more etched features.

11. The etched plate of claim 1, wherein the one or more etched features have straight walls, tapered walls, curved walls, textured walls, smooth walls, or a combination thereof.

12. The multi-well plate of claim 1, wherein each of the one or more etched features are between about 1 microns and 1000 microns.

13. A nano-array plate comprising:
a substrate;
a first layer at least partially disposed on the substrate;
one or more etched features that extends at least partially through the first layer toward the substrate, wherein the one or more etched features comprise an opening in the first layer connected to bottom by one or more side walls; and
one or more micro-posts or micro-needles positioned at least partially within at least one of the one or more etched features.

14. The nano-array plate of claim 13, wherein the one or more micro-posts or micro-needles extend from the bottom, the one or more micro-posts or micro-needles extend downwardly from a second substrate positioned above the one or more etched features.

15. The nano-array plate of claim 13, wherein each of the one or more etched features are between about 1 microns and 1000 microns in diameter and each of the one or more micro-posts or micro-needles are between about 1 and 1000 microns.

16. The nano-array plate of claim 13, further comprising an agent binding surface on at least a portion of the one or more etched features to bind one or more agents selected from molecules, complexes, DNA, RNA, PNA, lipids, particles, nanoparticles, metal particles, surface functional groups, carboxylates, esters, alcohols, carbamides, aldehydes, amines, sulfur oxides, nitrogen oxides, halides, carbohydrates, ligands, receptors, pharmaceuticals, silanes, silanization groups, antigens, allergens, cells, antibodies, peptides, proteins, polymers, monomers, histones, other biomolecules, synthetic molecules or complexes.

17. The nano-array plate of claim 13, further comprising one or more electrodes in contact with the one or more nano-wells for cellular lysis, separation, dielectrophoresis, electroporation, well cleaning or non-analyte detection purposes.

18. The nano-array plate of claim 13, wherein the one or more micro-posts or micro-needles are optically transparent to form one or more lenses for detection of a signal.

19. The nano-array plate of claim 13, wherein the one or more micro-posts or micro-needles are at least partially optically transparent and positioned to emit light, to receive emissions from a sample in the nano-well or a combination thereof.

20. The nano-array plate of claim 13, wherein one or more micro-posts or micro-needles are hollow for sample delivery.

21. The nano-array plate of claim 13, further comprising an imaging system adapted to fit the nano-array plate to measure one or more parameters from the one or more etched features.

22. The nanoarray plate of claim 21, wherein the one or more parameters comprises impedance measurements, polarography, potentiometry, cyclic voltammetry, amperometric analysis, conductance analysis or a combination thereof.

23. A method of forming a nano-array titer plate comprising the steps of:
providing a first layer in contact with a substrate; and
forming one or more etched features in the first layer to form a nano-array titer plate, wherein each of the one or more etched features comprise an opening connected to a bottom by one or more side walls.

24. The method of claim 23, wherein first layer comprises 1, 2, 3, 4, 5, 6, 7, 8, 9 or more independent layers.

25. The method of claim 23, wherein the one or more etched features extend through the first layer to the substrate.

26. The method of claim 23, further comprising the integration of one or more detection methods on a micro-post, a micro-needle, one of the one or more etched or combination thereof selected from antigen-antibody, antibody-antigen, Sandwich ELISA, aptamers, enzyme-substrate, receptor-ligand, protein-drug, protein-liposome, and antibody-carbohydrate, rolling circle amplification, radioisotope labeling, surface-enhanced laser desorption/ionization (SELDI) mass spectrometry, atomic force microscopy, surface plasmon resonance, planar waveguide, and electrochemical detection.

27. The method of claim 23, wherein the nano-array titer plate comprising more than 5,000 etched features.

28. The method of claim 23, wherein the substrate is formed by
positioning a working electrode at a first depth in the substrate,
covering the working electrode with a passive layer;
uncovering at least a portion of the passive layer that corresponds to the one or more etched features;
positioning a second electrode in proximity to the working electrode; and
bonding the substrate to the first layer.

29. The method of claim 23, further comprising one or more micro-posts or micro-needles extending upwardly from the bottom of at least one of the one or more etched features, or extending downwardly from a separate substrate into at least one or more of the etched features, or a combination thereof.

30. The nanoarray plate of claim 28, wherein each of the one or more etched features are between about 1 microns and 1000 microns in diameter and each of the one or more micro-posts or micro-needles are between about 1 and 1000 microns.

31. A method for measuring electrode induced property in a etched features assay array having more than 5,000 etched features comprising the steps of:
providing a etched features assay array comprising a first layer at least partially disposed on a substrate, at least 5,000 etched features at least partially in the first layer extending from the substrate, wherein each of the more than 5,000 etched features comprising an opening in the first layer connected to a bottom by one or more side walls and a first electrode and a second electrode within the more than 5,000 etched features;
providing electrical energy to the first electrode, the second electrode or both the first and second electrodes; and
measuring one or more electrode induced property generated in at least one of the more than 5,000 etched features.
